(19) United States
(12) Patent Application Publication
(10) Pub. No.: US 2025/0185327 A1
(43) Pub. Date: Jun. 5, 2025

(54) RESONANT TUNNELING DIODE AND TERAHERTZ OSCILLATOR

(71) Applicant: SONY GROUP CORPORATION, Tokyo (JP)

(72) Inventors: Masahiro MURAYAMA, Kanagawa (JP); Takahiro KOYAMA, Kanagawa (JP)

(21) Appl. No.: 18/839,967

(22) PCT Filed: Mar. 16, 2023
(86) PCT No.: PCT/JP2023/010416

§ 371 Date: Aug. 20, 2024

(30) Foreign Application Priority Data
Mar. 31, 2022 (JP) 2022-060131

(51) Int. Cl. H10D 62/815; H03B 7/08; H10D 8/75; H10D 62/85; H10D 62/852

(52) U.S. Cl. CPC H10D 62/8164; H03B 7/08; H10D 8/755; H10D 62/8503; H10D 62/852

(57) ABSTRACT

To provide a resonant tunneling diode and a terahertz oscillator capable of further performance improvement. The resonant tunneling diode includes: a multi-quantum well structure that is composed of a group-III nitride semiconductor; a first electrode that is connected to one of sides of the multi-quantum well structure; and a second electrode that is connected to the other side of the multi-quantum well structure. The multi-quantum well structure includes a first barrier layer, a first quantum well layer, a second barrier layer, a second quantum well layer, and a third barrier layer, which are arranged in order from the first electrode toward the second electrode. The first barrier layer, the second barrier layer, and the third barrier layer have a thickness through which a carrier can pass by a tunneling effect. The first quantum well layer and the second quantum well layer each have a potential gradient by spontaneous polarization or a sum of spontaneous polarization and piezoelectric polarization, and have mutually different thicknesses. The first quantum well layer and the second quantum well layer have compositions with different magnitudes of potential energy.

### TECHNICAL FIELD

The present disclosure relates to a resonant tunneling diode and a terahertz oscillator.

### BACKGROUND ART

A resonant tunneling diode (RTD) is a diode that utilizes resonant tunneling. Resonant tunneling is a phenomenon where carriers such as electrons and holes having energies equivalent to the quantum level of a quantum well held between potential barriers tunnel through quantum wells. In the resonant tunneling diode, since the channel of an electron is restricted to the energy width of the resonance level of a quantum well, a negative resistance region appears at a certain voltage. A terahertz oscillator using this negative resistance region for THz oscillation has been known (see PTLs 1 and 2, for example).

In a typical GaAs-based resonant tunneling diode with double barriers, a resonant tunneling current flows when a bias is applied to the collector side and the Fermi level on the emitter side coincides with the quantum level (ground level) of a quantum well.

Furthermore, in a resonant tunneling diode with triple barriers, a resonant tunneling current flows at a bias at which the quantum levels (ground levels) of two quantum wells match. Compared to the resonant tunneling diode with double barriers, the resonant tunneling diode with triple barriers has a narrower energy distribution of transmitted electrons at resonance, so that a steep rise of a peak current is obtained (see PTL 3 and PTL 4, for example).

### CITATION LIST

### Patent Literature

### [PTL 1]

JP 2018-67727 A

### [PTL 2]

JP 2020-88466 A

### [PTL 3]

JP S63-124578 A

### [PTL 4]

JP 2009-152547 A

### SUMMARY

### Technical Problem

In this technical field, further performance improvement is desired.

The present disclosure has been contrived in view of such circumstances, and an object of the present disclosure is to provide a resonant tunneling diode and a terahertz oscillator capable of further performance improvement.

### Solution to Problem

A resonant tunneling diode according to one aspect of the present disclosure includes: a multi-quantum well structure that is composed of a group-III nitride semiconductor; a first electrode that is connected to one side of the multi-quantum well structure and is applied a first voltage when the resonant tunneling diode is operated; and a second electrode that is connected to the other side of the multi-quantum well structure and is applied a second voltage lower than the first voltage when the resonant tunneling diode is operated. The multi-quantum well structure includes a first barrier layer, a first quantum well layer, a second barrier layer, a second quantum well layer, and a third barrier layer, which are arranged in order from the first electrode toward the second electrode. The first barrier layer, the second barrier layer, and the third barrier layer have a thickness through which a carrier can pass by a tunneling effect. The first quantum well layer and the second quantum well layer each have a potential gradient by spontaneous polarization or a sum of spontaneous polarization and piezoelectric polarization, and have mutually different thicknesses. The first quantum well layer and the second quantum well layer have compositions with different magnitudes of potential energy.

Accordingly, resonant tunneling through the ground level of the first quantum well layer and the ground level of the second quantum well layer becomes possible, and the barriers can have a height that takes advantage of the group-III nitride semiconductor. Consequently, a peak-to-valley current ratio (PVCR) can be increased. Moreover, the triangular potential can be reduced or eliminated by the second quantum well. As a result, even in a case where some of the carriers transit from the second level to the ground level, the electrons that made the transition to the ground level can be prevented from accumulating in the triangular potential. Thus, the occurrence of a hysteresis phenomenon in the current-voltage characteristics (I-V characteristics) can be prevented. The resonant tunneling diode is capable of not only realizing a high PVCR but also realizing I-V characteristics in which the occurrence of a hysteresis phenomenon is suppressed, so that further performance improvement can be achieved.

A resonant tunneling diode according to another aspect of the present disclosure includes: a multi-quantum well structure that is composed of a group-III nitride semiconductor; a first electrode that is connected to one side of the multi-quantum well structure and is applied a first voltage when the resonant tunneling diode is operated; and a second electrode that is connected to the other side of the multi-quantum well structure and is applied a second voltage lower than the first voltage when the resonant tunneling diode is operated. The multi-quantum well structure includes a first barrier layer, a first quantum well layer, a second barrier layer, a second quantum well layer, and a third barrier layer, which are arranged in order from the first electrode toward the second electrode. The first barrier layer, the second barrier layer, and the third barrier layer have a thickness through which a carrier can pass by a tunneling effect. The first quantum well layer and the second quantum well layer each have a potential gradient by spontaneous polarization or a sum of spontaneous polarization and piezoelectric polarization, and have mutually different thicknesses. At least either one of the first quantum well layer and the second quantum well layer has a potential inclination generated by a composition gradient.

Therefore, as with the resonant tunneling diode according to the one aspect described above, this resonant tunneling diode is capable of not only realizing a high PVCR but also realizing I-V characteristics in which the occurrence of a hysteresis phenomenon is suppressed, so that further performance improvement can be achieved.

A terahertz oscillator according to one aspect of the present disclosure includes: an antenna; and a resonant tunneling diode connected to the antenna in parallel. The resonant tunneling diode includes: a multi-quantum well structure that is composed of a group-III nitride semiconductor; a first electrode that is connected to one side of the multi-quantum well structure and is applied a first voltage when the resonant tunneling diode is operated; and a second electrode that is connected to the other side of the multi-quantum well structure and is applied a second voltage lower than the first voltage when the resonant tunneling diode is operated. The multi-quantum well structure includes a first barrier layer, a first quantum well layer, a second barrier layer, a second quantum well layer, and a third barrier layer, which are arranged in order from the first electrode toward the second electrode. The first barrier layer, the second barrier layer, and the third barrier layer have a thickness through which a carrier can pass by a tunneling effect. The first quantum well layer and the second quantum well layer each have a potential gradient by spontaneous polarization or a sum of spontaneous polarization and piezoelectric polarization, and have mutually different thicknesses. The first quantum well layer and the second quantum well layer have compositions with different magnitudes of potential energy.

Therefore, since the high-performance resonant tunneling diode that with a high PVCR and a hysteresis phenomenon suppressed is used, the use of such resonant tunneling diode is expected to contribute to the reduction of variations in oscillation conditions and oscillation frequencies.

### BRIEF DESCRIPTION OF DRAWINGS

FIG. 1 is a cross-sectional diagram schematically showing a configuration example of a resonant tunneling diode (RTD) according to an embodiment of the present disclosure.

FIG. 2 is a graph schematically showing I-V characteristics of the resonant tunneling diode according to the embodiment of the present disclosure.

FIG. 3 is a diagram schematically showing an energy band structure of a conduction band at the time of a low bias in the resonant tunneling diode according to the embodiment of the present disclosure.

FIG. 4 is a diagram schematically showing an energy band structure of a conduction band at a peak point in the resonant tunneling diode according to the embodiment of the present disclosure.

FIG. 5 is a diagram schematically showing an energy band structure of a conduction band in a differential low resistance region of the resonant tunneling diode according to the embodiment of the present disclosure.

FIG. 6 is a schematic diagram showing a configuration of a resonant tunneling diode according to Comparative Example 1 of the present disclosure.

FIG. 7A is a diagram showing a result of a simulation of an energy band structure of the resonant tunneling diode according to Comparative Example 1 of the present disclosure.

FIG. 7B is a diagram showing a result of a simulation of the energy band structure of the resonant tunneling diode according to Comparative Example 1 of the present disclosure.

FIG. 8 is a schematic diagram showing a configuration of a resonant tunneling diode according to Comparative Example 2 of the present disclosure.

FIG. 9A is a diagram showing a result of a simulation of an energy band structure of the resonant tunneling diode according to Comparative Example 2 of the present disclosure.

FIG. 9B is a diagram showing a result of a simulation of the energy band structure of the resonant tunneling diode according to Comparative Example 2 of the present disclosure.

FIG. 10 is a schematic diagram showing a configuration of a resonant tunneling diode according to Comparative Example 3 of the present disclosure.

FIG. 11A is a diagram showing a result of a simulation of an energy band structure of the resonant tunneling diode according to Comparative Example 3 of the present disclosure.

FIG. 11B is a diagram showing a result of a simulation of the energy band structure of the resonant tunneling diode according to Comparative Example 3 of the present disclosure.

FIG. 12 is a schematic diagram showing a configuration of a resonant tunneling diode according to an example of the present disclosure.

FIG. 13A is a diagram showing a result of a simulation of an energy band structure of the resonant tunneling diode according to the example of the present disclosure.

FIG. 13B is a diagram showing a result of a simulation of the energy band structure of the resonant tunneling diode according to the example of the present disclosure.

FIG. 14 is a cross-sectional diagram showing a configuration of a resonant tunneling diode according to a modification of the embodiment of the present disclosure.

FIG. 15 is an equivalent circuit diagram of a terahertz oscillator that uses the resonant tunneling diode according to the embodiment of the present disclosure.

### DESCRIPTION OF EMBODIMENTS

An embodiment of the present disclosure will be described below with reference to the drawings. In descriptions of the drawings referred to in the following description, same or similar portions will be denoted by same or similar reference signs. However, it should be noted that the drawings are schematic, and the relationships between thicknesses and planar dimensions, ratios of thicknesses of respective layers, and the like are different from actual ones. Therefore, specific thicknesses and dimensions should be determined by considering the following descriptions. In addition, it is obvious that the drawings include portions where mutual dimensional relationships and ratios differ between the drawings.

It is to be understood that definitions of directions such as upward, downward, and the like in the following description are merely definitions provided for the convenience of explanation and are not intended as limiting the technical ideas of the present disclosure. For example, it is obvious that when an object is observed after being rotated by 90 degrees, up-down is converted into and interpreted as left-right, and when the object is observed after being rotated by 180 degrees, up down is interpreted as being inverted.

### (Configuration Example)

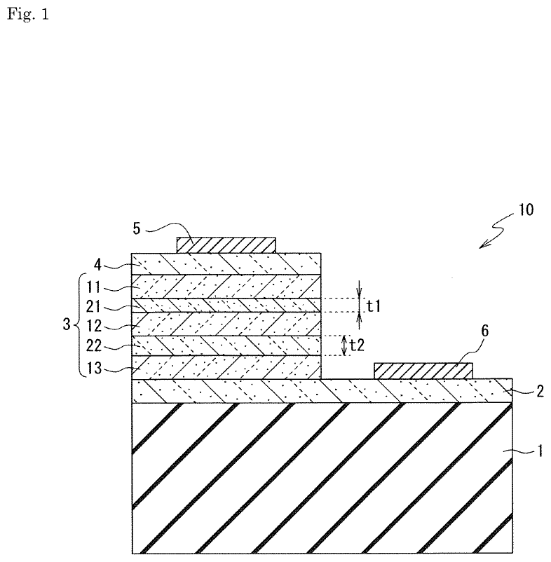

FIG. 1 is a cross-sectional diagram schematically showing a configuration example of a resonant tunneling diode (RTD) 10 according to an embodiment of the present disclosure. The resonant tunneling diode 10 according to the embodiment of the present disclosure is an n-type unipolar diode composed of a group-III nitride semiconductor. As shown in FIG. 1, the resonant tunneling diode 10 includes a substrate 1, a second contact layer 2 provided on the substrate 1, a multi-quantum well structure 3 provided on a first region of the second contact layer 2 (region on the left side in FIG. 1), a first contact layer 4 provided on the multi-quantum well structure 3, a first electrode 5 provided on the first contact layer 4, and a second electrode 6 provided on a second region of the second contact layer 2 (region on the right side in FIG. 1).

The substrate 1 is, for example, a semi-insulating substrate in which GaN (gallium nitride) or AlN (nitride) can grow, and is a non-doped Si substrate or a sapphire substrate. Also, SiC, sapphire, Si or the like may be used as the substrate 1.

The second contact layer 2 is, for example, an n-type GaN layer. The second contact layer 2 is arranged between the second electrode 6 and the multi-quantum well structure 3, and ohmically connects the second electrode 6 and the multi-quantum well structure 3 (e.g., a third barrier layer 13, described later).

The multi-quantum well structure 3 has a structure in which a plurality of barrier layers and a plurality of quantum well layers are layered alternately. Each of the barrier layers is arranged at both ends of this layered structure. For example, the multi-quantum well structure 3 has a first barrier layer 11, a first quantum well layer 21, a second barrier layer 12, a second quantum well layer 22, and the third barrier layer 13. The third barrier layer 13 is arranged on the first region of the second contact layer 2, the second quantum well layer 22 is arranged on the third barrier layer 13, the second barrier layer 12 is arranged on the second quantum well layer 22, the first quantum well layer 21 is arranged on the second barrier layer 12, and the first barrier layer 11 is arranged on the first quantum well layer 21. That is, the third barrier layer 13, the second quantum well layer 22, the second barrier layer 12, the first quantum well layer 21, and the first barrier layer 11 are layered in this order on the second contact layer 2.

For example, the second contact layer 2, the third barrier layer 13, the second quantum well layer 22, the second barrier layer 12, the first quantum well layer 21, the first barrier layer 11, and the first contact layer 4 are deposited in this order by a MOCVD (Metal Organic Chemical Vapor Deposition) method.

The first barrier layer 11, the second barrier layer 12, and the third barrier layer 13 are each composed of an n-type group-III nitride semiconductor, and each have a thickness through which a carrier (e.g., an electron e−) can pass by a tunneling effect. The first barrier layer 11, the second barrier layer 12, and the third barrier layer 13 each have a wider bandgap than the first quantum well layer 21 and the second quantum well layer 22, and are each made of a material having a higher energy level of a conduction band than those of the first quantum well layer 21 and the second quantum well layer 22. For example, the material constituting the first barrier layer 11, the second barrier layer 12, and the third barrier layer 13 is InGaN, GaN, AlGaN, AlN, AlInN, or AlInGaN. The conductivity type of these materials are n-type.

The first quantum well layer 21 and the second quantum well layer 22 are each composed of a group-III nitride semiconductor and each have a potential gradient by spontaneous polarization or a sum of spontaneous polarization and piezoelectric polarization. The first quantum well layer 21 and the second quantum well layer 22 have mutually different thicknesses. For example, as shown in FIG. 1, when the thickness of the first quantum well layer 21 is t1 and the thickness of the second quantum well layer is t2, t1<t2 is established.

In addition, the first quantum well layer 21 and the second quantum well layer 22 have compositions with mutually different potential energies (electron affinity). For example, a material constituting the first quantum well layer 21 and the second quantum well layer 22 is n-type InxGayN (0≤x≤1, 0≤y≤1, x+y=1) or n-type AlxGayN (0≤x≤1, 0≤y≤1, x+y=1). At least either one of the first quantum well layer 21 and the second quantum well layer 22 has a potential inclination generated by a composition gradient in a thickness direction.

For example, the first quantum well layer 21 is a GaN layer, and the second quantum well layer 22 is an InxGayN layer (0.2≤x≤0.4, 0.6≤y≤0.8, x+y=1). The composition ratio x of the InxGayN layer constituting the second quantum well layer 22 has a composition gradient where the composition ratio x gradually decreases from 0.4 to 0.2 from the interface between the second quantum well layer 22 and the third barrier layer 13 toward the interface between the second quantum well layer 22 and the second barrier layer 12. The composition ratio y of the InxGayN layer constituting the second quantum well layer 22 has a composition gradient where the composition ratio y gradually increases from 0.6 to 0.8 from the interface between the second quantum well layer 22 and the third barrier layer 13 toward the interface between the second quantum well layer 22 and the second barrier layer 12.

Therefore, the first quantum well layer 21 and the second quantum well layer 22 have mutually different potential energy magnitudes. For example, when the potential energy of the first quantum well layer 21 is E1 and the potential energy of the second quantum well layer 22 is E2, E1>E2 is established.

The first contact layer 4 is, for example, an n-type GaN layer. The first contact layer 4 is arranged between the first electrode 5 and the multi-quantum well structure 3, and ohmically connects the first electrode 5 and the multi-quantum well structure 3 (e.g., the first barrier layer 11, described later).

The first electrode 5 is a collector electrode. The first electrode 5 is composed of, for example, a simple metal such as Al, Au, Cr, Ti, or Ni, or a metal electrode obtained by alloying these metals.

The second electrode 6 is an emitter electrode. The second electrode 6 is composed of, for example, a simple metal such as Al, Au, Cr, Ti, or Ni, or a metal electrode obtained by alloying these metals.

### (Characteristics)

In FIG. 1, when a voltage is applied between the first electrode 5 and the second electrode 6 of the resonant tunneling diode 10 (i.e., a bias voltage is applied), the carrier (e.g., electron) moves from the second electrode 6, which is the emitter electrode, to the first electrode 5, which is the collector electrode. During this process, the electron passes through the third barrier layer 13 by the tunneling effect, passes through the second quantum well layer 22 via the quantum level, passes through the second barrier layer 12 by the tunneling effect, passes through the first quantum well layer 21 via the quantum level, and passes through the first barrier layer 11 by the tunneling effect. Therefore, the current flows from the second electrode 6 to the first electrode 5.

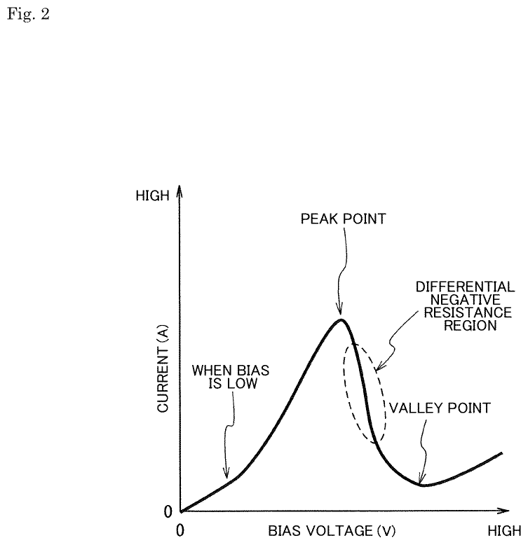

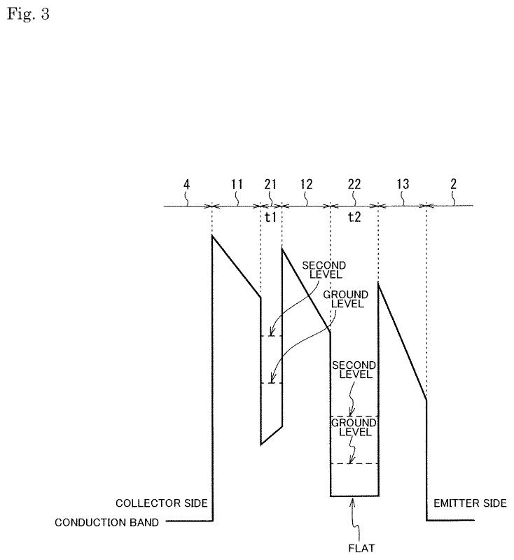

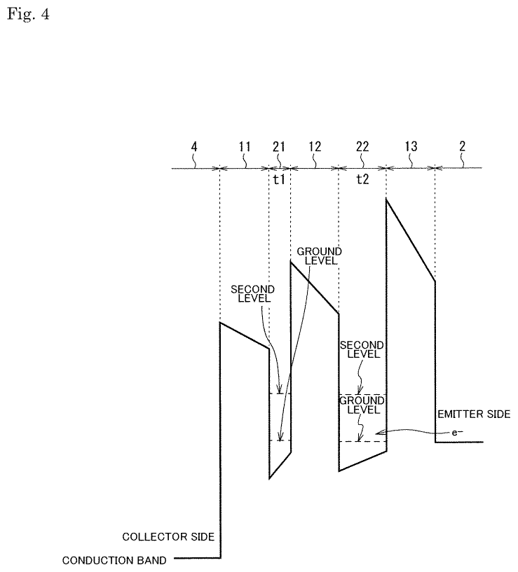

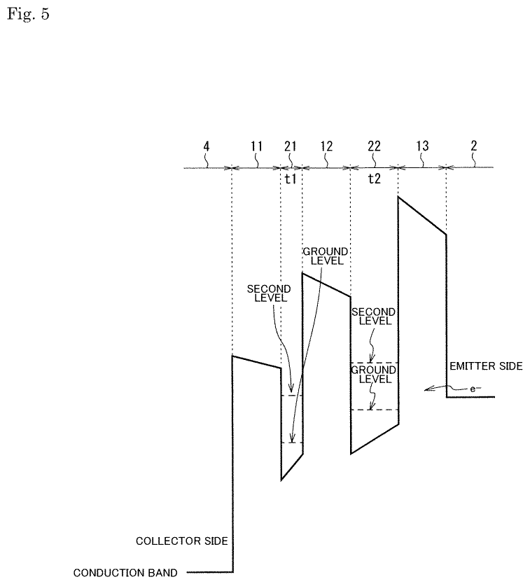

FIG. 2 is a graph schematically showing current-voltage characteristics (I-V characteristics) of the resonant tunneling diode 10 according to the embodiment of the present disclosure. The horizontal axis of FIG. 2 shows a bias voltage (V) of the resonant tunneling diode 10 and the vertical axis shows a current (A) flowing to the resonant tunneling diode 10. FIG. 3 is a diagram schematically showing an energy band structure of a conduction band at the time of a low bias in the resonant tunneling diode 10 according to the embodiment of the present disclosure. FIG. 4 is a diagram schematically showing an energy band structure of a conduction band at a peak point in the resonant tunneling diode 10 according to the embodiment of the present disclosure. FIG. 5 is a diagram schematically showing an energy band structure of a conduction band in a differential low resistance region of the resonant tunneling diode 10 according to the embodiment of the present disclosure.

As shown in FIG. 2, the I-V characteristics of the resonant tunneling diode 10 have a tendency where the current increases up to the peak point in a direction of increase of a DC bias voltage, the current decreases to the valley point after passing the peak point, and increases again after passing the valley point. This is because, as shown in FIGS. 3 to 5, the resonant tunneling diode 10 has the first barrier layer 11, the second barrier layer 12, and the third barrier layer 13, and a large resonant tunneling current flows at the bias voltage where the quantum levels of the first quantum well layer 21 and the second quantum well layer 22 match (i.e., the peak point).

In the resonant tunneling diode 10, as a result of constantly applying a bias voltage, the current can no longer tunnel and decreases when the quantum levels within quantum well layers fall below the bottom of the conduction band of the emitter. As shown in FIG. 2, the region where the current decreases with respect to the bias voltage is a differential negative resistance region.

The resonant tunneling diode 10 is composed of a group-III nitride semiconductor that has piezoelectric polarization (piezoelectric polarization) in crystals, as is illustrated in, for example, a GaN-based material. Thus, by utilizing, for example, a wide bandgap change from AlN to GaN to InN, it is possible to form a quantum well layer/barrier layer structure having a large barrier energy.

In addition, compared to a resonant tunneling diode with double barriers (e.g., Comparative Example 1 described later), the resonant tunneling diode 10 with triple barriers has a narrower energy distribution of transmitted electrons at resonance. Thus, the resonant tunneling diode 10 can obtain a sharp rise of a peak current, and a negative resistance in the differential negative resistance region can be increased.

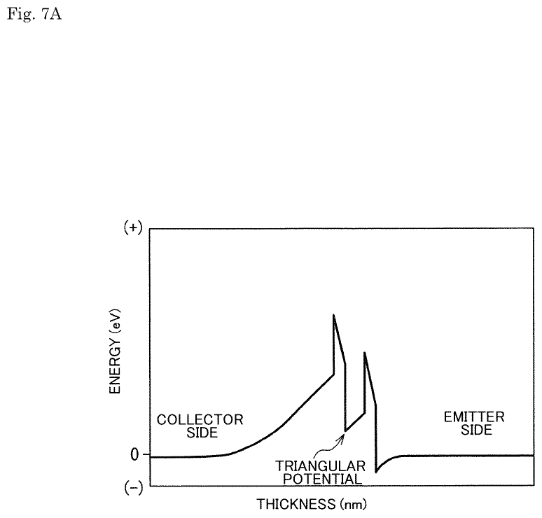

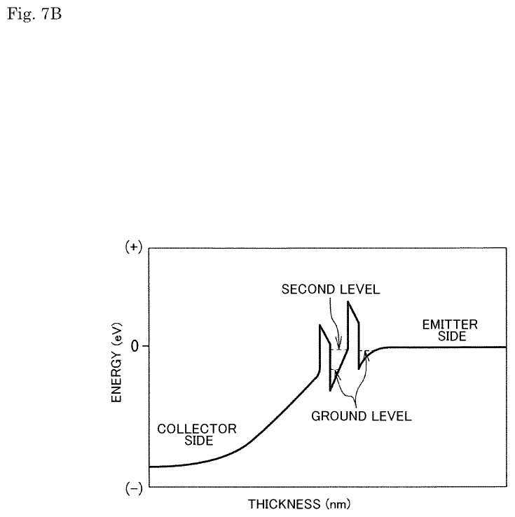

Furthermore, the second quantum well layer 22 has a composition gradient in which the bandgap gradually becomes wide along a crystal growth direction (i.e., toward the second barrier layer 12). Since the second quantum well layer 22 has such composition gradient in the thickness direction, the triangular potential within the second quantum well layer 22 (see FIGS. 7A, 9A, 11A described later) can be made almost flat in an equilibrium state in which a bias voltage is not applied.

More specifically, the triangular potential is generated by the effect of a potential gradient by spontaneous polarization or a sum of spontaneous polarization and piezoelectric polarization. In the resonant tunneling diode 10, the second quantum well layer 22 has a potential inclination obtained by the composition gradient in the thickness direction. This composition gradient relaxes the potential gradient obtained by spontaneous polarization or a sum of spontaneous polarization or piezoelectric polarization. That is, the composition gradient of the second quantum well layer 22 relaxes the potential gradient obtained by spontaneous polarization or a sum of spontaneous polarization and piezoelectric polarization. Therefore, the resonant tunneling diode 10 can reduce or eliminate the triangular potential (or make it almost flat). By making the triangular potential almost flat, an effective increase in film thickness of the second barrier layer 12 can be suppressed, and resonant tunneling via the ground level of the second quantum well layer 22 can be made possible.

Further, since the triangular potential is reduced or eliminated in the second quantum well layer 22, even when some of the electrons transit from the second level to the ground level, the electrons that made the transition can be prevented from accumulating in the triangular potential. Thus, the accumulated electrons can be prevented from changing the electronic conduction properties of the second quantum well layer 22 before and after bias application, so that the occurrence of a hysteresis phenomenon in the I-V characteristics of the resonant tunneling diode 10 can be suppressed.

Moreover, by making the film thickness of the first quantum well layer 21 thinner than that of the second quantum well layer 22, it becomes easier to create the state in which the energy of the ground level of the first quantum well layer 21 and the energy of the ground level of the second quantum well layer 22 match upon bias application. As a result, the resonant tunneling current via the ground level of the first quantum well layer 21 and the ground level of the second quantum well layer 22 can be allowed to flow effectively.

As described above, the resonant tunneling diode 10 can realize a high peak-to-valley current ratio (PVCR) and also realize highly reproducible I-V characteristics that prevent the occurrence of a hysteresis phenomenon.

Supplemental descriptions of spontaneous polarization and piezoelectric polarization are now provided. In a case where a substrate is composed of GaN and a quantum well layer is composed of GaN (i.e., the quantum well layer and the substrate are composed of a material of the same composition), the quantum well layer has spontaneous polarization. In a case where the substrate is composed of GaN and the quantum well layer is composed of InGaN or AlGaN (i.e., the quantum well layer and the substrate are composed of materials of different compositions), the quantum well layer has both spontaneous polarization and piezoelectric polarization, and an electric field gradient within the quantum well layer is determined by the balance therebetween. In the embodiment of the present disclosure, since the material of the substrate is not limited to GaN, the quantum well layers have a potential gradient by spontaneous polarization or a sum of spontaneous polarization and piezoelectric polarization. The barrier layers also have both spontaneous polarization and piezoelectric polarization and as a result have a potential gradient. Thus, as shown in FIGS. 3 to 5, the upper portions of the energy bands of the barrier layers, too, have an inclined shape.

Next, examples and comparative examples of the present disclosure are illustrated to explain the technology of the present disclosure in more detail. Comparative Examples 1 to 3 will be illustrated first, and thereafter the examples will be illustrated.

### Comparative Example 1

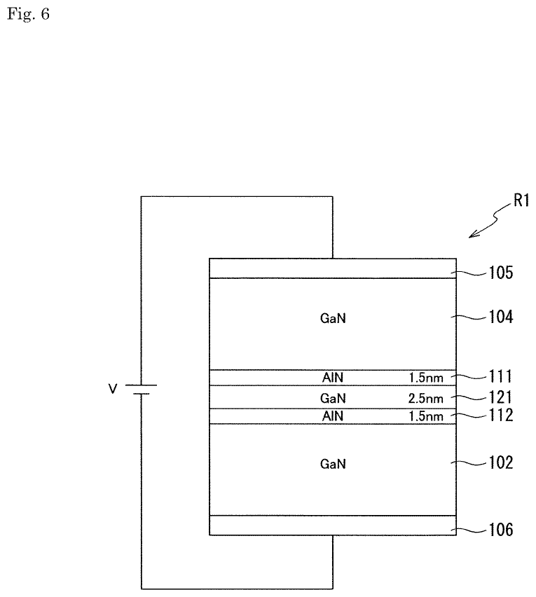

FIG. 6 is a schematic diagram showing a configuration of a resonant tunneling diode R1 according to Comparative Example 1 of the present disclosure. As shown in FIG. 6, the resonant tunneling diode R1 according to Comparative Example 1 is a unipolar diode composed of a group-III nitride semiconductor and having double barriers. The resonant tunneling diode R1 includes a second electrode 106, a second contact layer 102 connected ohmically to the second electrode 106, a second barrier layer 112 provided on the second contact layer 102, a quantum well layer 121 provided on the second barrier layer 112, a first barrier layer 111 provided on the quantum well layer 121, a first contact layer 104 provided on the first barrier layer 111, and a first electrode 105 connected ohmically to the first contact layer 104.

The first electrode 105 is a collector electrode, and the second electrode 106 is an emitter electrode. The first electrode 105 and the second electrode 106 are connected to a power supply device V in such a manner that a positive bias voltage is applied to the first electrode 105 and 0 V is applied to the second electrode 106.

In Comparative Example 1, the first contact layer 104, the second contact layer 102, and the quantum well layer 121 are each composed of GaN. The first barrier layer 111 and the second barrier layer 112 are each composed of AlN. The first barrier layer 111 and the second barrier layer 112 each have a thickness of 1.5 nm. The thickness of the quantum well layer 121 is 2.5 nm.

FIGS. 7A and 7B are diagrams showing a result of a simulation of an energy band structure of the resonant tunneling diode R1 according to Comparative Example 1 of the present disclosure. FIG. 7A shows the energy band structure obtained when a bias voltage is not applied (unapplication), and FIG. 7B shows the energy band structure obtained when a bias voltage of 5 V is applied (application of 5 V).

In Comparative Example 1, a strong resonant tunneling current was observed in the vicinity of 5.2 V. Judging from the energy band structure upon application of 5 V shown in FIG. 7B, the above-mentioned observation is presumably due to a resonant tunneling phenomenon via the second level of the quantum well layer 121.

Further, the quantum well layer 121 is composed of GaN. Therefore, as shown in FIG. 7A, in the energy band structure upon bias unapplication, the potential of the quantum well layer 121 is distorted by the effect of spontaneous polarization or a sum of spontaneous polarization and piezoelectric polarization and has a triangular shape. Due to the effect of this triangular potential, the film thickness of the first barrier layer 111 at the ground level increases effectively, and the resonant tunneling current cannot flow easily via the ground level. Therefore, in Comparative Example 1, the tunneling current is considered to flow mainly via the second level.

In resonant tunneling via the second level, some of the carriers (e.g., electrons) transit from the second level to the ground level in the tunneling process (i.e., energy relaxation), and accumulate in the triangular potential of the quantum well layer 121. Since the accumulated electrons change the electronic conduction properties of the first quantum well layer 121 before and after bias application, a hysteresis phenomenon occurs in the I-V characteristics.

### Comparative Example 2

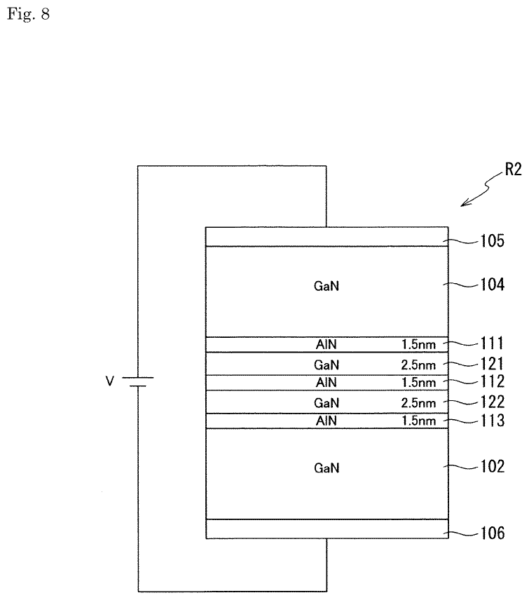

FIG. 8 is a schematic diagram showing a configuration of a resonant tunneling diode R2 according to Comparative Example 2 of the present disclosure. The resonant tunneling diode R2 according to Comparative Example 2 is different from the resonant tunneling diode R1 according to Comparative Example 1 in having triple barriers. The resonant tunneling diode R2 includes a third barrier layer 113 provided on the second contact layer 102, a second quantum well layer 122 provided on the third barrier layer 113, a second barrier layer 112 provided on the second quantum well layer 122, a first quantum well layer 121 provided on the second barrier layer 112, and the first barrier layer 111 provided on the first quantum well layer 121.

In Comparative Example 2, the first quantum well layer 121 and the second quantum well layer 122 are each composed of GaN. The first quantum well layer 121 and the second quantum well layer 122 each have a thickness of 2.5 nm.

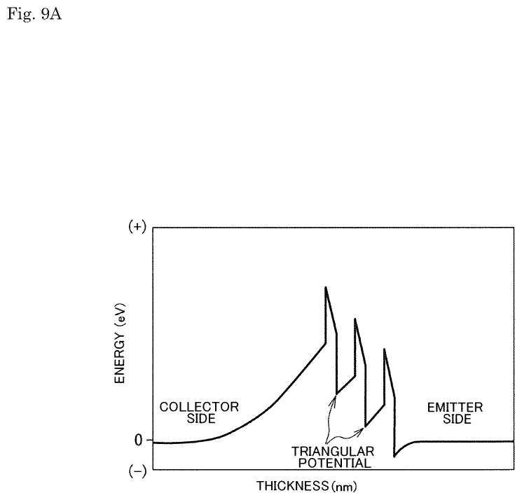

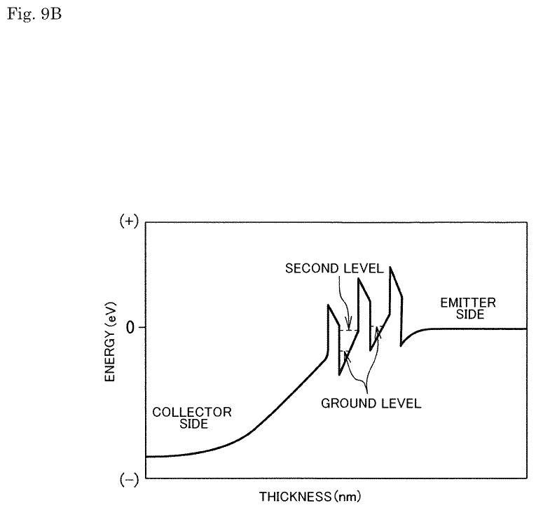

FIGS. 9A and 9B are diagrams showing a result of a simulation of an energy band structure of the resonant tunneling diode R2 according to Comparative Example 2 of the present disclosure. FIG. 9A shows the energy band structure upon unapplication, and FIG. 9B shows the energy band structure upon application of 5 V.

As with Comparative Example 1, in Comparative Example 2 as well, a strong resonant tunneling current was observed in the vicinity of 5.2 V. Judging from the energy band structure upon application of 5 V shown in FIG. 9B, the above-mentioned observation is presumably due to a resonant tunneling phenomenon via the second level of the quantum well layer 121.

Also, in Comparative Example 2 as well, in the energy band structure upon bias unapplication, the potentials of the first quantum well layer 121 and the second quantum well layer 122 are distorted by the effect of spontaneous polarization or a sum of spontaneous polarization and piezoelectric polarization and have a triangular shape. Due to the effect of the triangular potentials, the film thicknesses of the first barrier layer 111 and the second barrier layer 12 at the ground level increase effectively, and the resonant tunneling current cannot flow easily via the ground level. Therefore, in Comparative Example 2 as well, the tunneling current is considered to flow mainly via the second level.

In resonant tunneling via the second level, since some of the carriers (e.g., electrons) accumulate in the triangular potential within the quantum well layer 121 in the tunneling process, a hysteresis phenomenon occurs in the I-V characteristics. Therefore, in the GaN-based resonant tunneling diode R2, simply providing triple barriers could not improve the resonant tunneling current sufficiently; thus, it was found out that the resonant tunneling diode R2 has room for improvement.

### Comparative Example 3

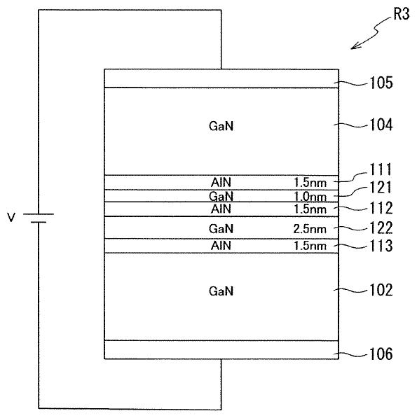

FIG. 10 is a schematic diagram showing a configuration of a resonant tunneling diode R3 according to Comparative Example 3 of the present disclosure. The resonant tunneling diode R3 according to Comparative Example 3 is different from the resonant tunneling diode R2 according to Comparative Example 2 in that the thickness of the first quantum well layer 121 is thinner than that of the second quantum well layer 122. The thickness of the first quantum well layer 121 is 1.0 nm, and the thickness of the second quantum well layer 122 is 2.5 nm.

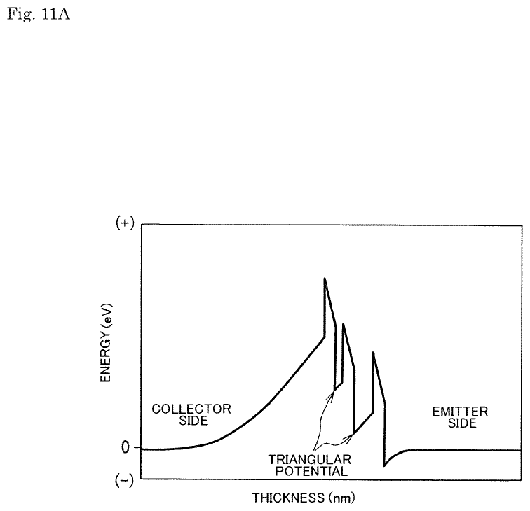

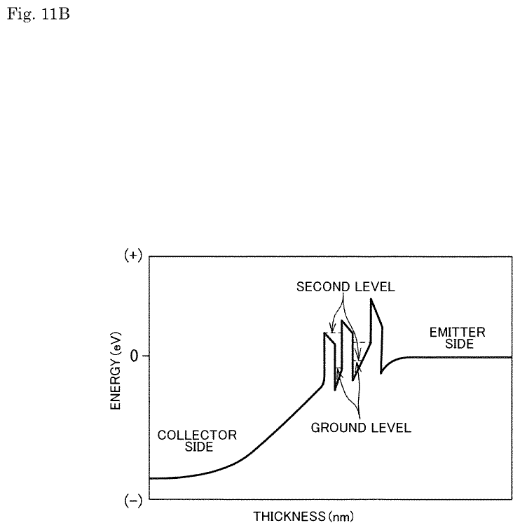

FIGS. 11A and 11B are diagrams showing a result of a simulation of an energy band structure of the resonant tunneling diode R3 according to Comparative Example 3 of the present disclosure. FIG. 11A shows the energy band structure upon unapplication, and FIG. 11B shows the energy band structure upon application of 5 V. In Comparative Example 3, a resonant tunneling current that is larger and steeper in the vicinity of 5.2 V compared to Comparative Example 2 was observed. Judging from the energy band structure upon application of 5 V shown in FIG. 11B, the above-mentioned observation is presumably due to a resonant tunneling phenomenon via the second level of the quantum well layer 121.

Also, in Comparative Example 3 as well, in the energy band structure upon bias unapplication, the potentials of the first quantum well layer 121 and the second quantum well layer 122 are distorted by the effect of spontaneous polarization or a sum of spontaneous polarization and piezoelectric polarization and have a triangular shape. Therefore, in Comparative Example 3 as well, the tunneling current is considered to flow mainly via the second level. For example, the tunneling current is considered to flow mainly via the second level of the first quantum well layer 121 and the second level of the second quantum well layer 122. Due to the presence of triangular potentials in the first quantum well layer 121 and the second quantum well layer 122, a hysteresis phenomenon occurs in the I-V characteristics. According to Comparative Example 3 as well, it was found out that the resonant tunneling current has room for improvement.

### Example

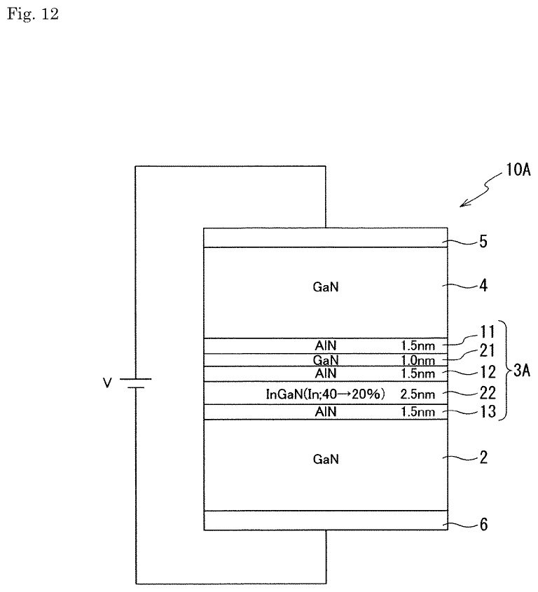

FIG. 12 is a schematic diagram showing a configuration of a resonant tunneling diode 10A according to an example of the present disclosure. The resonant tunneling diode 10A according to Example 10A includes a second electrode 6, a second contact layer 2 connected ohmically to the second electrode 6, a third barrier layer 13 provided on the second contact layer 2, a second quantum well layer 22 provided on the third barrier layer 13, a second barrier layer 12 provided on the second quantum well layer 22, a first quantum well layer 21 provided on the second barrier layer 12, a first barrier layer 11 provided on the first quantum well layer 21, a first contact layer 4 provided on the first barrier layer 11, and a first electrode 5 connected ohmically to the first contact layer 4. A multi-quantum well structure 3A is configured by the first barrier layer 11, the first quantum well layer 21, the second barrier layer 12, the second quantum well layer 22, and the third barrier layer 13.

In the example, the first contact layer 4, the second contact layer 2, and the first quantum well layer 21 are each composed of GaN. The second quantum well layer 22 is an InxGayN layer (0.2≤x 0.4, 0.6≤y 0.8, x+y=1). The composition ratio x of the InxGayN layer constituting the second quantum well layer 22 has a composition gradient where the composition ratio x gradually decreases from 0.4 to 0.2 from the interface between the second quantum well layer 22 and the third barrier layer 13 toward the interface between the second quantum well layer 22 and the second barrier layer 12. The composition ratio y of the InxGayN layer constituting the second quantum well layer 22 has a composition gradient where the composition ratio y gradually increases from 0.6 to 0.8 from the interface between the second quantum well layer 22 and the third barrier layer 13 toward the interface between the second quantum well layer 22 and the second barrier layer 12. Accordingly, the potential energy of the second quantum well layer 22 (electron affinity) is different in magnitude from the potential energy of the first quantum well layer 21.

The first barrier layer 11, the second barrier layer 12, and the third barrier layer 13 are each composed of AlN. The first barrier layer 11, the second barrier layer 12, and the third barrier layer 13 each have a thickness of 1.5 nm. The thickness of the quantum well layer 121 is 2.5 nm. The thickness of the first quantum well layer 21 is 1.5 nm. The second quantum well layer 22 is 2.5 nm.

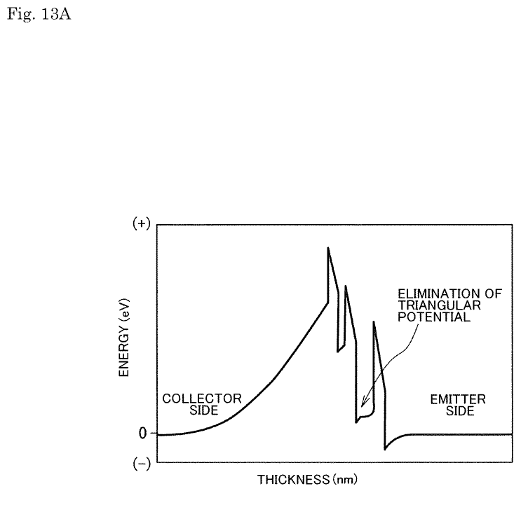

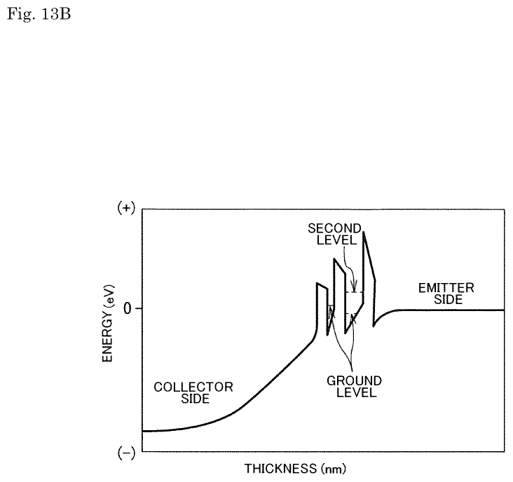

FIGS. 13A and 13B are diagrams showing a result of a simulation of an energy band structure of the resonant tunneling diode 10A according to the example of the present disclosure. FIG. 13A shows the energy band structure obtained when a bias voltage is not applied (unapplication), and FIG. 13B shows the energy band structure obtained when a bias voltage of 5 V is applied (application of 5 V).

As shown in FIG. 13A, in the example, the triangular potential of the second quantum well layer 22 is reduced or eliminated in the energy band structure obtained upon bias unapplication, and is almost flat. Due to this effect, an effective increase in film thickness of the second barrier layer 12 can be suppressed, and resonant tunneling via the ground level can be made possible. Although not shown, in the example, when the bias voltage was approximately 5.2 V, a stronger current peak was observed as compared with each of the structures of Comparative Examples 1 to 3. Judging from the energy band structure upon application of 5 V shown in FIG. 13B, the above-mentioned observation is presumably due to the fact that the resonant tunneling current flew via the ground level of the first quantum well layer 21 and the ground level of the second quantum well layer 22.

In the resonant tunneling diodes R1, R2, R3 according to Comparative Examples 1 to 3, it was difficult to obtain a resonant tunneling current obtained via the ground levels of quantum well layer. In the resonant tunneling diodes R1, R2, R3 according to Comparative Examples 1 to 3, since a current flowing via the ground equal to or higher than the second level is obtained, the effective barrier height becomes low, and therefore the characteristics of the GaN-based materials with a large bandgap difference cannot be utilized.

On the other hand, the resonant tunneling diode 10A according to the example can achieve resonant tunneling via the ground levels of quantum well layers and obtain the barrier height that takes advantage of the GaN-based materials. Thus, the peak-to-valley current ratio (PVCR) can be increased.

In addition, in the example, since the triangular potential of the second quantum well layer 22 is reduced or eliminated, even when some of the electrons transit from the second level to the ground level (i.e., energy relaxation), the electrons that made the transition can be prevented from accumulating in the triangular potential. Thus, the occurrence of a hysteresis phenomenon in the I-V characteristics can be suppressed.

### (Advantageous Effects of Embodiment)

As described above, the resonant tunneling diode 10 according to Embodiment 1 of the present disclosure includes the multi-quantum well structure 3 composed of a group-III nitride semiconductor, the first electrode 5 that is connected to one of the sides of the multi-quantum well structure 3 and is applied the first voltage (e.g., 5 V) when the resonant tunneling diode is operated, and the second electrode 6 that is connected to the other side of the multi-quantum well structure 3 and is applied the second voltage (e.g., 0 V) lower than the first voltage when the resonant tunneling diode is operated.

The multi-quantum well structure 3 has the first barrier layer 11, the first quantum well layer 21, the second barrier layer 12, the second quantum well layer 22, and the third barrier layer 13, which are arranged in order from the first electrode 5 toward the second electrode 6. The first barrier layer 11, the second barrier layer 12, and the third barrier layer 13 have a thickness through which a carrier (e.g., electron) can pass by a tunneling effect. The first quantum well layer 21 and the second quantum well layer 22 each have a potential gradient by spontaneous polarization or a sum of spontaneous polarization and piezoelectric polarization, and the thicknesses t1, t2 different from each other. The first quantum well layer 21 and the second quantum well layer 22 have compositions with mutually different potential energies.

Thus, resonant tunneling via the ground level of the first quantum well layer 21 and the ground level of the second quantum well layer 22 becomes possible, and the barriers can have a height that takes advantage of the group-III nitride semiconductor. Consequently, a peak-to-valley current ratio (PVCR) can be increased.

That is, the effective thicknesses of the first barrier layer 11 and the second barrier layer 12 can be reduced, and at the same a large tunneling current between the ground levels can be generated. Since the barrier height of the first barrier layer 11 and the second barrier layer 12 is kept high, an overflow of electrons from the first barrier layer 11 and the second barrier layer 12 can be suppressed. Consequently, an extremely high PVCR can be realized as compared with the prior art.

Moreover, since the triangular potential of the second quantum well layer 22 is reduced or eliminated, even in a case where some of the electrons transit from the second level to the ground level in the tunneling process, the electrons that made the transition to the ground level can be prevented from accumulating in the triangular potential. Thus, the occurrence of a hysteresis phenomenon in the I-V characteristics can be suppressed.

As described above, since the resonant tunneling diode 10 can not only realize an extremely high PVCR but also realize highly reproducible I-V characteristics that prevent the occurrence of a hysteresis phenomenon, further performance improvement is possible.

### (Modifications)

The foregoing embodiment has described that the resonant tunneling diode 10 has triple barriers. The example, too, has described that the resonant tunneling diode 10A has triple barriers. However, in the embodiment of the present disclosure, the barriers of the resonant tunneling diode are not limited to triple barriers. The resonant tunneling diode may have quadruple barriers or five or more barriers.

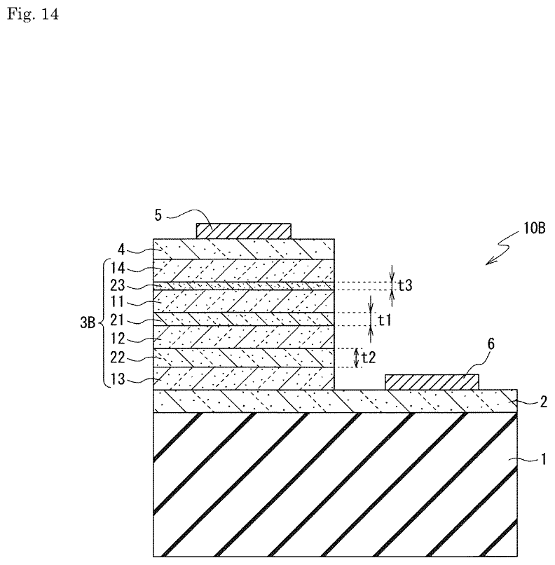

FIG. 14 is a cross-sectional diagram showing a configuration of a resonant tunneling diode 10B according to a modification of the embodiment of the present disclosure. As shown in FIG. 14, a multi-quantum well structure 3B of the resonant tunneling diode 10B has a fourth barrier layer 14 and a third quantum well layer 23 in addition to the configuration of the multi-quantum well structure 3 shown in FIG. 1. The fourth barrier layer 14 is arranged opposite the first quantum well layer 21 across the first barrier layer 11. The third quantum well layer 23 is arranged between the fourth barrier layer 14 and the first barrier layer 11.

When the thickness of the first quantum well layer 21 is t1, the thickness of the second quantum well layer 22 is t2, and the thickness of the third quantum well layer 23 is t3, t3<t1<t2 is established.

The second contact layer 2, the third barrier layer 13, the second quantum well layer 22, the second barrier layer 12, the first quantum well layer 21, the first barrier layer 11, and the first contact layer 4 are deposited in this order by a MOCVD (Metal Organic Chemical Vapor Deposition) method.

The resonant tunneling diode 10B having such a configuration exerts the same advantageous effects as the resonant tunneling diode 10 described in the foregoing embodiment. For example, in the resonant tunneling diode 10B, resonant tunneling via the ground level of the first quantum well layer 21, the ground level of the second quantum well layer 22, and the ground level of the third quantum well layer 23 becomes possible, and the barriers can have a height that takes advantage of the group-III nitride semiconductor.

As a result, the PVCR can be increased. Further, in the multi-quantum well structure 3B as well, since the triangular potential of the second quantum well layer 22 is reduced or eliminated, the occurrence of a hysteresis phenomenon in the I-V characteristics can be suppressed. Since the resonant tunneling diode 10B can not only realize a high PVCR but also realize highly reproducible I-V characteristics that prevent the occurrence of a hysteresis phenomenon, performance improvement is possible.

### (Application Examples)

The resonant tunneling diode 10 according to the embodiment of the present disclosure, the resonant tunneling diode 10A according to the example, and the resonant tunneling diode 10B according to the modification of the embodiment can be applied to an oscillator that oscillates frequencies of a terahertz (THz) frequency band (approximately 0.1 THz to 10 THz) between radio waves and light waves.

As shown in FIG. 2, for example, differential negative resistance region where the current decreases with respect to the bias voltage is present in the I-V characteristics of the resonant tunneling diodes 10, 10A, 10B. By using this differential negative resistance region, electromagnetic waves can be oscillated and amplified. Also, the resonant tunneling diodes 10, 10A, 10B have a parasitic capacitance C_{RTD} in parallel with a differential negative resistance “−G_{RTD}.”

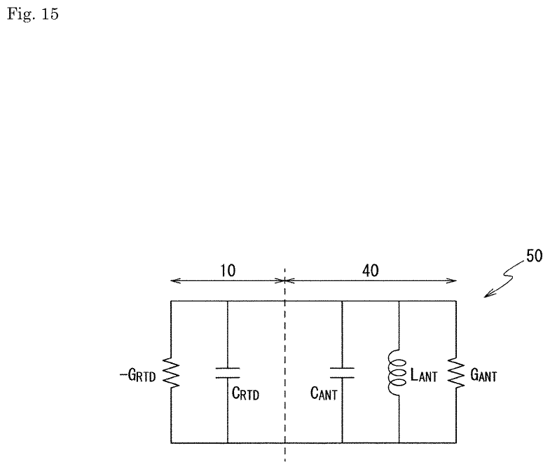

FIG. 15 is an equivalent circuit diagram of a terahertz oscillator 50 that uses the resonant tunneling diode 10 according to the embodiment of the present disclosure. As shown in FIG. 15, the terahertz oscillator 50 has the resonant tunneling diode 10 according to the embodiment of the present embodiment and a slot antenna 40 (an example of the “antenna” of the present disclosure). The resonant tunneling diode 10 and the slot antenna 40 are connected to each other in parallel.

In FIG. 15, C_{ANT} indicates the capacity that the slot antenna 40 has, L_{ANT} indicates the inductance that the slot antenna 40 has, and G_{ANT} indicates a radiation loss of the slot antenna 40. An oscillation initiation condition of the terahertz oscillator 50 is applied when a positive value G_{RTD} of the differential negative resistance characteristics “−G_{RTD}” becomes equal to or greater than the radiation loss G_{ANT}, as shown by the following formula (1). An oscillation frequency of the terahertz oscillator 50 is shown by the following formula (2)

$$\begin{matrix}[ Math . 1 ] & \\ Oscillation condition & ( 1 )\end{matrix}$$

$${G}_{RTD} ≧ {G}_{ANT}$$

$$\begin{matrix}[ Math . 2 ] & \\ Oscillation frequency & ( 2 )\end{matrix}$$

$$f = \frac{1}{2 π \sqrt{{L}_{ANT} ( {C}_{RTD} + {C}_{ANT} )}}$$

The output of the slot antenna 40 attenuates even with oscillation by a resistance component (radiation loss G_{ANT}) inherent in the slot antenna 40, and the differential negative resistance “−G_{RTD}” of the resonant tunneling diode 10 is used as a negative resistance component counteracting this resistance component (radiation loss G_{ANT}).

Since the terahertz oscillator 50 shown in FIG. 15 uses the high-performance resonant tunneling diode 10 having a high PVCR and suppressing a hysteresis phenomenon, the terahertz oscillator 50 is expected to be able to contribute to the reducing the variation in oscillation conditions or oscillation frequency f.

### Other Embodiments

While the present disclosure has been described on the basis of the embodiment and modifications as described above, the descriptions and figures that constitute parts of the present disclosure should not be understood as limiting the present disclosure. Various alternative embodiments, examples, and operable techniques will be apparent to those skilled in the art from the present disclosure.

For example, in the resonant tunneling diode according to the embodiment of the present disclosure, a spacer layer composed of n-type GaN or the like may be interposed between the multi-quantum well structure 3 and the second contact layer 2 and between the multi-quantum well structure 3 and the first contact layer 4.

In addition, the terahertz oscillator 50 shown in FIG. 15 may include the resonant tunneling diode 10A shown in FIG. 12 or the resonant tunneling diode 10B shown in FIG. 14 in place of the resonant tunneling diode 10.

Furthermore, the resonant tunneling diode according to the embodiment of the present disclosure may not be an n-type unipolar diode but may be a p-type unipolar diode. In a case where the resonant tunneling diode is a p-type unipolar diode, the carriers are holes.

Thus, it is obvious that the present technology includes various embodiments and the like that are not described herein. At least one of various omissions, substitutions, and modifications of components may be performed without departing from the gist of the embodiment and the modification described above. Furthermore, the advantageous effects described in the present specification are merely exemplary and not intended as limiting, and other advantageous effects may be produced.

The present disclosure can also take the following configurations.

(1)

A resonant tunneling diode, including:
a multi-quantum well structure that is composed of a group-III nitride semiconductor;
a first electrode that is connected to one side of the multi-quantum well structure and is applied a first voltage when the resonant tunneling diode is operated; and
a second electrode that is connected to the other side of the multi-quantum well structure and is applied a second voltage lower than the first voltage when the resonant tunneling diode is operated,
wherein the multi-quantum well structure includes
a first barrier layer, a first quantum well layer, a second barrier layer, a second quantum well layer, and a third barrier layer, which are arranged in order from the first electrode toward the second electrode,
the first barrier layer, the second barrier layer, and the third barrier layer having a thickness through which a carrier can pass by a tunneling effect,
the first quantum well layer and the second quantum well layer each having a potential gradient by spontaneous polarization or a sum of spontaneous polarization and piezoelectric polarization, and having mutually different thicknesses, and
the first quantum well layer and the second quantum well layer having compositions with different magnitudes of potential energy.
   (2)

The resonant tunneling diode according to (1) above, wherein at least either one of the first quantum well layer and the second quantum well layer has a potential inclination generated by a composition gradient.

(3)

A resonant tunneling diode, including:
a multi-quantum well structure that is composed of a group-III nitride semiconductor;
a first electrode that is connected to one side of the multi-quantum well structure and is applied a first voltage when the resonant tunneling diode is operated; and
a second electrode that is connected to the other side of the multi-quantum well structure and is applied a second voltage lower than the first voltage when the resonant tunneling diode is operated,
wherein the multi-quantum well structure includes
a first barrier layer, a first quantum well layer, a second barrier layer, a second quantum well layer, and a third barrier layer, which are arranged in order from the first electrode toward the second electrode,
the first barrier layer, the second barrier layer, and the third barrier layer having a thickness through which a carrier can pass by a tunneling effect,
the first quantum well layer and the second quantum well layer each having a potential gradient by spontaneous polarization or a sum of spontaneous polarization and piezoelectric polarization, and having mutually different thicknesses, and
at least either one of the first quantum well layer and the second quantum well layer having a potential inclination generated by a composition gradient.
   (4)

The resonant tunneling diode according to any one of (1) to (3) above, wherein
when the thickness of the first quantum well layer is t1 and the thickness of the second quantum well layer is t2, t1<t2 is established, and
when the potential energy of the first quantum well layer is E1 and the potential energy of the second quantum well layer is E2, E1>E2 is established.
   (5)

The resonant tunneling diode according to any one of (1) to (4) above, wherein a material constituting the first quantum well layer and the second quantum well layer is InxGayN (0≤x≤1, 0≤y≤1, x+y=1) or AlxGayN (0≤x≤1, 0≤y≤1, x+y=1), and
a material constituting the first barrier layer, the second barrier layer, and the third barrier layer is InGaN, GaN, AlGaN, AlN, AlInN, or AlInGaN.
   (6)

The resonant tunneling diode according to any one of (1) to (5) above, further including:
a first contact layer that is arranged between the first electrode and the multi-quantum well structure and ohmically connects the first electrode to the multi-quantum well structure; and
a second contact layer that is arranged between the second electrode and the multi-quantum well structure and ohmically connects the second electrode to the multi-quantum well structure,
wherein the first contact layer and the second contact layer are composed of a group-III nitride semiconductor.
   (7)

The resonant tunneling diode according to any one of (1) to (6) above, wherein the multi-quantum well structure includes:
a fourth barrier layer that is arranged opposite the first quantum well layer across the first barrier layer; and
a third quantum well layer that is arranged between the fourth barrier layer and the first barrier layer,
wherein when the thickness of the first quantum well layer is t1, the thickness of the second quantum well layer is t2, and a thickness of the third quantum well layer is t3, t3<t1<t2 is established.
   (8)

The resonant tunneling diode according to (2) or (3) above, wherein the potential gradient by the spontaneous polarization or a sum of the spontaneous polarization and the piezoelectric polarization is relaxed by the composition gradient.

(9)

A terahertz oscillator, including:
an antenna; and
a resonant tunneling diode that is connected to the antenna in parallel,
wherein the resonant tunneling diode includes:
a multi-quantum well structure that is composed of a group-III nitride semiconductor;
a first electrode that is connected to one side of the multi-quantum well structure and is applied a first voltage when the resonant tunneling diode is operated; and
a second electrode that is connected to the other side of the multi-quantum well structure and is applied a second voltage lower than the first voltage when the resonant tunneling diode is operated, and
the multi-quantum well structure includes
a first barrier layer, a first quantum well layer, a second barrier layer, a second quantum well layer, and a third barrier layer, which are arranged in order from the first electrode toward the second electrode,
the first barrier layer, the second barrier layer, and the third barrier layer having a thickness through which a carrier can pass by a tunneling effect,
the first quantum well layer and the second quantum well layer each having a potential gradient by spontaneous polarization or a sum of spontaneous polarization and piezoelectric polarization, and having mutually different thicknesses, and
the first quantum well layer and the second quantum well layer having compositions with different magnitudes of potential energy.

### REFERENCE SIGNS LIST

1 Substrate
2, 102 Second contact layer
3, 3A, 3B Multi-quantum well structure
4, 104 First contact layer
5, 105 First electrode
6, 106 Second electrode
10, 10A, 10B, R1, R2, R3 Resonant tunneling diode (RTD)
11, 111 First barrier layer
12, 112 Second barrier layer
13, 113 Third barrier layer
14 Fourth barrier layer
21 First quantum well layer
22 Second quantum well layer
23 Third quantum well layer
40 Slot antenna
50 Terahertz oscillator
121 (First) quantum well layer
V Power supply device

1. A resonant tunneling diode, comprising:
a multi-quantum well structure that is composed of a group-III nitride semiconductor;
a first electrode that is connected to one side of the multi-quantum well structure and is applied a first voltage when the resonant tunneling diode is operated; and
a second electrode that is connected to the other side of the multi-quantum well structure and is applied a second voltage lower than the first voltage when the resonant tunneling diode is operated,
wherein the multi-quantum well structure includes
a first barrier layer, a first quantum well layer, a second barrier layer, a second quantum well layer, and a third barrier layer, which are arranged in order from the first electrode toward the second electrode,
the first barrier layer, the second barrier layer, and the third barrier layer having a thickness through which a carrier can pass by a tunneling effect,
the first quantum well layer and the second quantum well layer each having a potential gradient by spontaneous polarization or a sum of spontaneous polarization and piezoelectric polarization, and having mutually different thicknesses, and
the first quantum well layer and the second quantum well layer having compositions with different magnitudes of potential energy.

2. The resonant tunneling diode according to claim 1, wherein at least either one of the first quantum well layer and the second quantum well layer has a potential inclination generated by a composition gradient.

3. A resonant tunneling diode, comprising:
a multi-quantum well structure that is composed of a group-III nitride semiconductor;
a first electrode that is connected to one side of the multi-quantum well structure and is applied a first voltage when the resonant tunneling diode is operated; and
a second electrode that is connected to the other side of the multi-quantum well structure and is applied a second voltage lower than the first voltage when the resonant tunneling diode is operated,
wherein the multi-quantum well structure includes
a first barrier layer, a first quantum well layer, a second barrier layer, a second quantum well layer, and a third barrier layer, which are arranged in order from the first electrode toward the second electrode,
the first barrier layer, the second barrier layer, and the third barrier layer having a thickness through which a carrier can pass by a tunneling effect,
the first quantum well layer and the second quantum well layer each having a potential gradient by spontaneous polarization or a sum of spontaneous polarization and piezoelectric polarization, and having mutually different thicknesses, and
at least either one of the first quantum well layer and the second quantum well layer having a potential inclination generated by a composition gradient.

4. The resonant tunneling diode according to claim 1, wherein when the thickness of the first quantum well layer is t1 and the thickness of the second quantum well layer is t2, t1<t2 is established, and
when the potential energy of the first quantum well layer is E1 and the potential energy of the second quantum well layer is E2, E1>E2 is established.

5. The resonant tunneling diode according to claim 1, wherein a material constituting the first quantum well layer and the second quantum well layer is InxGayN (0≤x≤1, 0≤y≤1, x+y=1) or AlxGayN (0≤x≤1, 0≤y≤1, x+y=1), and
a material constituting the first barrier layer, the second barrier layer, and the third barrier layer is InGaN, GaN, AlGaN, AlN, AlInN, or AlInGaN.

6. The resonant tunneling diode according to claim 1, further comprising:
a first contact layer that is arranged between the first electrode and the multi-quantum well structure and ohmically connects the first electrode to the multi-quantum well structure; and
a second contact layer that is arranged between the second electrode and the multi-quantum well structure and ohmically connects the second electrode to the multi-quantum well structure,
wherein the first contact layer and the second contact layer are composed of a group-III nitride semiconductor.

7. The resonant tunneling diode according to claim 1, wherein the multi-quantum well structure includes:
a fourth barrier layer that is arranged opposite the first quantum well layer across the first barrier layer; and
a third quantum well layer that is arranged between the fourth barrier layer and the first barrier layer,
wherein when the thickness of the first quantum well layer is t1, the thickness of the second quantum well layer is t2, and a thickness of the third quantum well layer is t3, t3<t1<t2 is established.

8. The resonant tunneling diode according to claim 2, wherein when the thickness of the first quantum well layer is t1 and the thickness of the second quantum well layer is t2, t1<t2 is established, and
when the potential energy of the first quantum well layer is E1 and the potential energy of the second quantum well layer is E2, E1>E2 is established.

9. The resonant tunneling diode according to claim 2, wherein a material constituting the first quantum well layer and the second quantum well layer is InxGayN (0≤x≤1, 0≤y≤1, x+y=1) or AlxGayN (0≤x≤1, 0≤y≤1, x+y=1), and
a material constituting the first barrier layer, the second barrier layer, and the third barrier layer is InGaN, GaN, AlGaN, AlN, AlInN, or AlInGaN.

10. The resonant tunneling diode according to claim 2, further comprising:
a first contact layer that is arranged between the first electrode and the multi-quantum well structure and ohmically connects the first electrode to the multi-quantum well structure; and
a second contact layer that is arranged between the second electrode and the multi-quantum well structure and ohmically connects the second electrode to the multi-quantum well structure,
wherein the first contact layer and the second contact layer are composed of a group-III nitride semiconductor.

11. The resonant tunneling diode according to claim 2, wherein the multi-quantum well structure includes:
a fourth barrier layer that is arranged opposite the first quantum well layer across the first barrier layer; and
a third quantum well layer that is arranged between the fourth barrier layer and the first barrier layer,
wherein when the thickness of the first quantum well layer is t1, the thickness of the second quantum well layer is t2, and a thickness of the third quantum well layer is t3, t3<t1<t2 is established.

12. The resonant tunneling diode according to claim 3, wherein when the thickness of the first quantum well layer is t1 and the thickness of the second quantum well layer is t2, t1<t2 is established, and
when a potential energy of the first quantum well layer is E1 and a potential energy of the second quantum well layer is E2, E1>E2 is established.

13. The resonant tunneling diode according to claim 3, wherein a material constituting the first quantum well layer and the second quantum well layer is InxGayN (0≤x≤1, 0≤y≤1, x+y=1) or AlxGayN (0≤x≤1, 0≤y≤1, x+y=1), and
a material constituting the first barrier layer, the second barrier layer, and the third barrier layer is InGaN, GaN, AlGaN, AlN, AlInN, or AlInGaN.

14. The resonant tunneling diode according to claim 3, further comprising:
a first contact layer that is arranged between the first electrode and the multi-quantum well structure and ohmically connects the first electrode to the multi-quantum well structure; and
a second contact layer that is arranged between the second electrode and the multi-quantum well structure and ohmically connects the second electrode to the multi-quantum well structure,
wherein the first contact layer and the second contact layer are composed of a group-III nitride semiconductor.

15. The resonant tunneling diode according to claim 3, wherein the multi-quantum well structure includes:
a fourth barrier layer that is arranged opposite the first quantum well layer across the first barrier layer; and
a third quantum well layer that is arranged between the fourth barrier layer and the first barrier layer,
wherein when the thickness of the first quantum well layer is t1, the thickness of the second quantum well layer is t2, and a thickness of the third quantum well layer is t3, t3<t1<t2 is established.

16. The resonant tunneling diode according to claim 2, wherein the potential gradient by the spontaneous polarization or a sum of the spontaneous polarization and the piezoelectric polarization is relaxed by the composition gradient.

17. A terahertz oscillator, comprising:
an antenna; and
a resonant tunneling diode that is connected to the antenna in parallel,
wherein the resonant tunneling diode includes:
a multi-quantum well structure that is composed of a group-III nitride semiconductor;
a first electrode that is connected to one side of the multi-quantum well structure and is applied a first voltage when the resonant tunneling diode is operated; and
a second electrode that is connected to the other side of the multi-quantum well structure and is applied a second voltage lower than the first voltage when the resonant tunneling diode is operated,
the multi-quantum well structure includes
a first barrier layer, a first quantum well layer, a second barrier layer, a second quantum well layer, and a third barrier layer, which are arranged in order from the first electrode toward the second electrode,
the first barrier layer, the second barrier layer, and the third barrier layer having a thickness through which a carrier can pass by a tunneling effect,
the first quantum well layer and the second quantum well layer each having a potential gradient by spontaneous polarization or a sum of spontaneous polarization and piezoelectric polarization, and having mutually different thicknesses, and
the first quantum well layer and the second quantum well layer having compositions with different magnitudes of potential energy.
